(19) United States
(12) Patent Application Publication
(10) Pub. No.: US 2015/0129027 A1
(43) Pub. Date: May 14, 2015

(54) Silicon Wafer Coated With A Passivation Layer

(71) Applicant: Dow Corning Corporaton, Midland, MI (US)

(72) Inventors: Syed Salman Asad, Ixelles (BE); Guy Beaucarne, Oud-Heverlee (BE); Pierre Descamps, Rixensart (BE); Vincent Kaiser, Pipaix (BE); Patrick Leempoel, Bruxelles (Uccle) (BE)

(73) Assignee: DOW CORNING CORPORATION, Midland, MI (US)

(21) Appl. No.: 14/402,320

(22) PCT Filed: Apr. 25, 2013
(86) PCT No.: PCT/US13/38108

§ 371 Date: Nov. 20, 2014

(30) Foreign Application Priority Data
May 31, 2012 (GB) 1209692.1
Mar. 13, 2013 (GB) 1304486.2

(51) Int. Cl. H01L 31/0216; H01L 31/18; H01L 31/0224; H01L 23/00

(52) U.S. Cl. CPC H01L 31/02167; H01L 23/564; H01L 31/18; H01L 31/022425
USPC 136/256; 257/632; 438/98

(57) ABSTRACT

Production of a silicon wafer coated with a passivation layer. The coated silicon wafer may be suitable for use in photovoltaic cells which convert energy from light impinging on the front face of the cell into electrical energy.

This invention relates to the production of a silicon wafer coated with a passivation layer. It is particularly concerned with coated silicon wafers suitable for use in photovoltaic cells which convert energy from light impinging on the front face of the cell into electrical energy. (The front face of a photovoltaic cell is the major surface facing the light source and the opposite major surface is the back surface.)

Photovoltaic cells are widely used as solar cells for providing electricity from impinging sunlight. Significant cost reduction of silicon solar cells requires a high throughput, low cost, and reliable industrial process on thin silicon wafer substrates. The thickness of the silicon wafer processed in mass production of solar cells has progressively decreased and is now about 180 μm; it is expected to be about 100 μm by 2020. This imposes significant modifications to the architecture of the solar cell because of cell bowing and loss of conversion efficiency. Cell bowing may result from a mismatch of the coefficients of thermal expansion of materials used in the cell.

Present industrial surface conditioning and back surface passivation processes do not meet the requirements for yield and performance on thin substrates. The currently dominating technology of Aluminum Back Surface Field (BSF) cell architecture, has reached its limits, particularly because of excessive cell bowing with wafers having thicknesses below about 200 μm following the high temperature (800° C.+) co-firing step generally used in solar cell production. Another issue is a loss in conversion efficiency due to creation of a defect rich zone (electron—hole recombination zone) in the region where aluminum diffuses into silicon at the back of the cell. As the wafer becomes thinner, this defective region may represent an increasingly significant fraction of the total active device thickness. Alternatives are required, particularly for back surface passivation.

One alternative solution relies on the use of dielectric layers for the passivation of the back surface, at least one of the layers of the stack being hydrogen rich to be used as a hydrogen source for dangling bonds passivation.

A paper by M. Tucci et al in Thin Solid Films (2008), 516(20), pages 6939-6942 describes thermal annealing after the sequential deposition by plasma enhanced chemical vapour deposition (PECVD) of a stack of hydrogenated amorphous silicon and hydrogenated amorphous silicon nitride to ensure stable passivation.

WO-A-2007/055484 and WO-A-2008/07828 disclose an alternative stack made of a silicon oxy-nitride (SiOₓN_{y}) passivation layer and a silicon nitride anti-reflective layer deposited on the back of the cell for surface passivation and optical trapping. The passivation layer is 10-50 nm thick while the anti-reflective layer is 50-100 nm thick.

WO-A-2006/110048 (US-A-2009/056800) discloses the deposition of a thin hydrogenated amorphous silicon or hydrogenated amorphous silicon carbide film, followed by the deposition of a thin hydrogenated silicon nitride film, preferably by PECVD (Plasma Enhanced Chemical vapor deposition) prior to a final anneal at high temperature in forming gas.

US-A-2007/0137699 describes a method for fabricating a solar cell comprising treating a silicon substrate in a plasma reaction chamber, forming a high efficiency emitter structure on the front face of the silicon substrate and forming a passivated structure on the second surface of the silicon substrate. The passivated back surface structure, comprising at least an SiO₂ layer and eventually also a hydrogenated amorphous silicon nitride layer, is made by PECVD at 120-240° C., introducing silane (SiH₄) and another reactive gas prior to igniting the plasma. The operating pressure ranges from 200 to 800 mTorr. SiO₂ is formed first, using oxygen as other reactive gas, directly on the back of the silicon wafer. The layer may be topped by a layer of silicon nitride made by introducing ammonia (NH₃) as other reactive gas.

US-A-2010/0323503 describes depositing a thin (0.1 to 10 nm) amorphous hydrogenated silicon layer on the surface to be passivated and converting it to SiO₂ by rapid thermal processing in an oxygen environment at between 750° C. and 1200° C. for 5 seconds to 30 minutes.

U.S. Pat. No. 7,838,400 describes forming a thin (2-15 nm) silicon oxide layer by rapidly heating the substrate at a rate of 200-400° C./second to a temperature of 800-1200° C. in the presence of oxygen and hydrogen at a pressure of 0.1-10 Torr and maintaining enough time to diffuse dopant previously deposited on one of the face of the substrate.

In Proceedings-Electrochemical Society (2003), 2003-1(Dielectrics in Emerging Technologies), 315-322, Journal of Applied Physics (2003), 94(5), 3427-3435 and Materials Research Society Symposium Proceedings (2002), 716(Silicon Materials—Processing, Characterization and Reliability), 569-574, A. Grill and co-workers describe the deposition of low k dielectric (a low dielectric constant oxide, lower than dense SiO₂) to be used for the microelectronic market. SiOC films are deposited from an organosilicon compound precursor and an additional organic material to deposit carbon rich SiOC. The additional organic material is chosen so that firing is accompanied by the elimination of thermally less stable organic fractions, creating a certain amount of porosity and hence decreasing the film density.

WO-A-2006/097303 and US-A-2009/0301557 describe a method for the production of a photovoltaic device, for instance a solar cell, by depositing a dielectric layer on the rear surface of a semiconductor substrate and depositing a passivation layer comprising hydrogenated SiN on top of the dielectric layer to form a stack and forming back contacts through this stack.

WO-A-2006/048649, WO-A-2006/048650 and WO-A-2012/010299 describe generating a non-equilibrium atmospheric pressure plasma incorporating an atomised surface treatment agent by applying a radio frequency high voltage to at least one electrode positioned within a dielectric housing having an inlet and an outlet while causing a process gas to flow from the inlet past the electrode to the outlet. The electrode is combined with an atomiser for the surface treatment agent within the housing. The non-equilibrium atmospheric pressure plasma extends from the electrode at least to the outlet of the housing so that a substrate placed adjacent to the outlet is in contact with the plasma.

The Ph.D thesis by Arjen Boogaart at Universiteit Twente, Netherlands, entitled “Plasma enhanced chemical deposition of silicon dioxide”, mentions the deposition of a silicon oxide film with negative fixed charges; however, negative fixed charges were only measured for very thin films (<50 nm), while the thicker films showed positive fixed charges and lower passivation performances. This was explained by a two layers model, one layer exhibiting negative fixed charges while the other positive fixed charges and hence the net charge on the overall film was the resultant of these two layers. The first layer was a very thin (limited thickness due to the bombarding ion energy, similar to oxidation process) oxide layer at the Si/SiOx interface with negative fixed charges formed due to predisposition oxygen impingement from plasma, while the second silicon oxide like layer that was deposited by PECVD contained positive fixed charges, therefore we may observe overall fixed negative charges if and only if the second layer is very thin. As a result, this invention cannot then be used in a PERC (Passivated Emitter and Rear Contacts) structure where thick oxide layers are required for optical reasons.

In a silicon wafer substrate coated with a silicon oxide layer according to the present invention, the silicon oxide has negative fixed charges and comprises an interface region and a bulk region more remote from the silicon wafer substrate than the interface region, wherein the bulk region has the formula SiOₓ where x has a mean value (the bulk value) greater than 2 and less than 2.6 as measured by EELS-TEM, and the interface region has the formula SiO_{y} wherein the ratio y of oxygen to silicon gradually increases over the thickness of the interface region from zero at the silicon wafer to x in the bulk region, the thickness of the interface region being in the range 5 to 20 nm measured by TEM.

TEM (Transmission Electron Microscopy) is a microscopy technique whereby a beam of electrons is transmitted through an ultra thin specimen, interacting with the specimen as it passes through. An image is formed from the interaction of the electrons transmitted through the specimen; the image is magnified and focused onto an imaging device, such as a fluorescent screen, on a layer of photographic, or to be detected by a sensor such as a CCD camera. TEMs are capable of imaging at a significantly higher resolution than light microscopes, owing to the small de Broglie wavelength of electrons. TEM has been used to visualize the x-section of a thin slice of the wafer/silicon oxide assembly of the present invention, allowing interface width measurement with high accuracy (precision of ˜2 Å). The symbol “˜” means approximately or about. The TEM measurement was complemented by electron energy loss spectroscopy (EELS) in which the material is exposed to a beam of electrons with a known, narrow range of kinetic energies, typically 100 to 300 keV so that the incident electrons pass entirely through the material sample in the transmission electron microscope. Some of the electrons will undergo inelastic scattering, which means that they lose energy and have their paths slightly and randomly deflected. The amount of energy loss can be measured by an electron spectrometer and interpreted in terms of what caused the energy loss. One can thereby determine the types of atoms, and the numbers of atoms of each type being struck by the beam.

The presence of the interface region in the coated silicon wafer is an essential part of this invention. We have found that passivation performance decreases with the thickness of this zone of graded oxygen concentration. The analytical method for interface thickness measurement is thus important. We have found that the use of high resolution TEM gives the highest accuracy of measurement of all the techniques we tried.

The value of x in the formula SiOₓ and the thickness of the interface region can alternatively be measured by secondary ion mass spectrometry (SIMS). In SIMS, the composition of solid surfaces and thin films is analyzed by sputtering the surface of the specimen with a focused primary ion beam and collecting and analyzing ejected secondary ions. These secondary ions are measured with a mass spectrometer to determine the elemental composition of the surface. For analysis of the silicon oxide and interface regions of some Examples of the present invention, dynamic SIMS has been used, wherein the varying composition of a layer throughout its depth can be measured by continued sputtering with continued mass spectrometry. However SIMS is less accurate than EELS-TEM for measuring interface thicknesses. Interface thickness measured by SIMS on same samples can be larger, even by a factor of 2. The difference comes from the low resolution of the SIMS technique itself specially while etching the film for depth profiling.

SIMS measurements can be complemented by X-ray photoelectron spectroscopy (XPS) measurement after etching. XPS allows measurement of film composition but the depth of film analysis is less than 10 nm and the result can be highly affected by surface contamination of the sample. To overcome this weakness and obtain a bulk film composition to complement SIMS results, XPS measurements can be carried out after etching the film with a 4 keV argon ion sputtering beam, alternating etching and data acquisition.

The silicon oxide which is coated on the silicon wafer substrate according to the present invention generally contains Si—OH bonds. The concentration of Si—OH bonds is such that the ratio between the surface area of the Si—OH peak located at 3000 cm⁻¹ to the surface area of the Si—O—Si peak located at 1060 cm⁻¹ as measured by FTIR is between 0.05 and 0.8. FTIR means Fourier transform infrared spectroscopy. An FTIR spectrometer simultaneously collects spectral data of light absorbance in a wide spectral range. A Fourier transform (a mathematical algorithm) is used to convert the raw data into the actual spectrum. The computer performing the Fourier transform generally also calculates the surface area of any peak in the spectrum. The structure of the FTIR absorption peak around 3000 cm⁻¹ suggests that silanols are present in the bulk and not on the film surface. Both the 0 and Si profile measured by SIMS and the silicon concentration measured by EELS-TEM shows a substantially constant silanol concentration all over the material x-section confirming an oxygen rich silicon oxide bulk material. When referring to a numerical range, the term “between” does not include the endpoints of the numerical range. For example, between 2 and 2.6 means from >2 to <2.6.

The invention includes a process for the production of a photovoltaic cell, wherein the silicon oxide layer of a silicon wafer substrate coated with a silicon oxide layer as defined above is hydrogenated and back contacts are formed through the silicon oxide layer.

We have found that the silicon oxide layer having negative fixed charges and an interface region in which the ratio y of oxygen to silicon atoms varies from the value x in the bulk to zero over the thickness of the interface region as defined above forms a particularly effective passivation layer after hydrogenation. Negative fixed charges (and resulting improved passivation) stay present when depositing thick SiOₓ films (of thickness>100 nm) which is of high interest for PERC type solar cells. Indeed, PERC cell architecture demands a thick silicon oxide layer to improve the performance of the rear side reflector and consequently the cell conversion efficiency. As a result, the silicon oxide layer subject to present invention allows combining improved rear side surface passivation and improved rear side reflector in the IR range.

The silicon wafer substrate which is coated is generally crystalline and can be mono-crystalline or multi-crystalline silicon. A mono-crystalline wafer can for example be a float-zone (FZ) silicon wafer, a Czochralski process (CZ) silicon wafer or a quasi-mono type silicon wafer. The silicon wafer substrate can for example be 100 μm to 400 μm.

The silicon oxide layer of the formula SiOₓ is preferably formed by thermally treating a layer of an organosilicon compound in an oxygen-containing atmosphere at a temperature of at least 600° C. (e.g., at least 700° C.) for 1 to 60 seconds, during which treatment the deposited layer is subject to a maximum temperature in the range 600 to 1050° C. The silicon compound preferably contains carbon and hydrogen in addition to silicon and oxygen. Preferably the silicon compound has been deposited on the silicon wafer substrate as a layer of density at least 1050 kg/m³. Unless otherwise indicated the density of the film is measured by:
1) measuring film thickness using a spectroscopic ellipsometer UVsel from Jobin-Yvon.
2) measuring the film weight using a weighing scale with a precision of 10⁻⁶ g
3) using the wafer surface area provided by manufacturer to determine the volume and then determining the density film density.

This deposited layer of silicon compound is generally formed from an organosilicon compound precursor. Examples of suitable organosilicon compounds include low molecular weight linear siloxanes such as hexamethyldisiloxane ((CH₃)₃)Si)₂O, octamethyltrisiloxane or decamethyltetrasiloxane, including siloxanes containing one or more Si—H group such as heptamethyltrisiloxane, cyclosiloxanes such as cyclooctamethyltetrasiloxane, cyclodecamethylpentasiloxane or tetramethylcyclotetrasiloxane (CH₃(H)SiO)₄, alkoxysilanes such as tetraethoxysilane (ethylorthosilicate) Si(OC₂H₅)₄ or methyltrimethoxysilane. The organosilicon compound precursor preferably contains silicon, carbon, oxygen and hydrogen atoms.

The deposited layer of silicon compound is preferably formed by chemical modification of the organosilicon compound precursor, for example by a polymerisation process which comprises siloxane condensation and/or an oxidation process. The layer of silicon compound deposited preferably has a lower carbon content than the organosilicon compound precursor. However we have found that if the layer of silicon compound deposited contains at least 5% carbon it is more readily oxidised to a silicon oxide layer of the formula SiOₓ as defined above by subsequent thermal treatment in an oxygen-containing atmosphere. The layer of silicon compound before thermal treatment preferably contains 5 to 66% carbon atoms (calculated as the proportion of carbon atoms in the deposited layer to total atoms excluding hydrogen), the maximum carbon content being dependant on the chemical composition of the silicon compound precursor being used.

The layer of silicon compound deposited preferably has a density in the range 1200 to 2000 kg/m³, alternatively 1500 to 2000 kg/m³. This is higher than the density of most organosilicon compounds, but lower than the density of a dielectric silica layer. The thickness of the layer of silicon compound deposited may be from 50 nm to 1 μm. Alternatively the thickness of the layer deposited may be from 100 nm, preferably from 200 nm, up to 600 nm.

In one preferred method, the layer of silicon compound is deposited from a non-local thermal equilibrium atmospheric pressure plasma interacting with an organosilicon compound. The layer of silicon compound may comprise a product of the interaction (e.g., plasma generated activated species and/or fragments of the organosilicon compound). Alternative methods of depositing the layer of silicon compound include low pressure plasma deposition and deposition and cross-linking of wet chemicals.

Plasma can in general be any type of non-equilibrium atmospheric pressure plasma. A preferred example is a non-local thermal equilibrium atmospheric pressure plasma discharge including dielectric barrier discharge and diffuse dielectric barrier discharge such as glow discharge plasma.

In a process for depositing the layer of silicon compound on a silicon wafer substrate from a non-local thermal equilibrium atmospheric pressure plasma, the process may for example comprise applying a radio frequency high voltage to at least one needle electrode positioned within a dielectric housing having an inlet and an outlet while causing a process gas to flow from the inlet through a channel past the electrode to the outlet, thereby generating a non-local thermal equilibrium atmospheric pressure plasma, incorporating an organosilicon compound in the non-local thermal equilibrium atmospheric pressure plasma so that the organosilicon compound interacts with the non-local thermal equilibrium atmospheric pressure plasma, and positioning the silicon wafer substrate adjacent to the outlet of the dielectric housing so that the surface of the silicon wafer substrate is in contact with activated organosilicon compound species and organosilicon compound fragments generated by plasma-organosilicon compound interaction.

The non-local thermal equilibrium atmospheric pressure plasma may extend from the electrode to the outlet of the dielectric housing so that the surface of the silicon wafer substrate adjacent to the outlet of the dielectric housing is in contact with the plasma. However the plasma need not extend to the outlet of the dielectric housing provided that the silicon wafer substrate is in contact with activated organosilicon compound species and organosilicon compound fragments generated by plasma-organosilicon compound interaction. Such activated organosilicon compound species and organosilicon compound fragments can be conveyed by the process gas flow, diffusion and possibly electric field to the surface of the silicon wafer substrate.

The deposited layer of silicon compound is preferably thermally treated in an oxygen-containing atmosphere at a temperature of at least 600° C. for 1 to 60 seconds, during which treatment the deposited layer is subject to a maximum temperature in the range 600 to 1050° C. For example, the deposited layer of silicon compound is preferably thermally treated in an oxygen-containing atmosphere at a temperature of at least 700° C. for 1 to 60 seconds, during which treatment the deposited layer is subject to a maximum temperature in the range 700 to 1050° C. This short time high temperature treatment can for example be achieved using an in-line furnace of the type used by the photovoltaic industry for the thermal contact annealing step of solar cell fabrication or using a RTP (Rapid Thermal Process) furnace like the RTP furnace provide by SSI. The time of treatment at above 600° C. (e.g., at above 700° C., particularly at least 750° C.) is more preferably less than 30 seconds and is most preferably less than 10 seconds, for example in the range 1 to 10 seconds. There may be no plateau in the furnace temperature profile; once the maximum temperature is reached the heating may be stopped immediately thus cooling the furnace down.

The oxygen-containing atmosphere used for the thermal treatment can for example contain 10 to 100%, alternatively 10 to 50% oxygen. The oxygen is preferably mixed with an inert gas such as nitrogen. Conveniently the oxygen-containing atmosphere can be air.

We believe that the formation of the material subjected to present invention that presents improved passivation performances is a result of at least 3 competitive processes during the thermal treatment step which are favourably balanced under the conditions of the present invention:
1. Oxygen diffuses across the film from film side exposed to oxygen atmosphere to the bulk of the film, up to the silicon wafer surface
2. Oxygen reacts with carbon/carbon hydrogen radicals, leading to carbon elimination from the film, and to the formation of Si—OH bonds in addition to Si—OH bonds already present in the film prior firing. The presence of carbon improves film restructuring to a structure having an oxygen rich (SiOx with x>2) bulk composition and an interface region of thickness<20 nm, which we believe is significant in the formation of a film having a low density of interface traps.
3. The Si—OH bonds formed during deposition or during the thermal treatment step may convert to S—O—Si bonds, particularly if the thermal treatment temperature is for example above 700° C. or 750° C., or above 900° C., thereby converting the film to a dense SiO2. Layer. For the present invention, the silanol condensation reaction SiOH->SiOSi need not to go to completion so that the final bulk material contains some SiOH bonds and the film remains oxygen rich.

The maximum temperature to which the silicon compound layer is subject during oxidative thermal treatment is preferably at least 700° C., alternatively at least 750° C., for example it may be in the range 700° to 1000° C., alternatively 750 to 1000° C. The thermal treatment is preferably sufficient to remove all carbon from the silicon compound, so that after thermal treatment the deposited layer of silicon compound contains no carbon as measured by X-ray photoelectron spectroscopy (XPS). The oxidative thermal treatment converts the deposited layer of silicon compound into a silicon oxide dielectric material of the formula SiOₓ where x has an average value between 2 and less than 2.6 as measured by EELS-TEM. The absence of carbon in the silicon oxide coatings shows that reaction 2) is faster than reaction 3) for short exposure of the film at high temperature, such as less than 60 seconds at 600° C. or less than 1 second at 900° C., carbon is eliminated from the film while internal silanols are still present.

The silicon oxide dielectric material of the formula SiOₓ where x has an average value comprised between 2 and 2.6 shows negative fixed charge and has a low density of interface traps. We believe that these features correlate with improved passivation when used in a photovoltaic cell such as a solar cell.

The invention will now be described with reference to the accompanying drawings, of which:

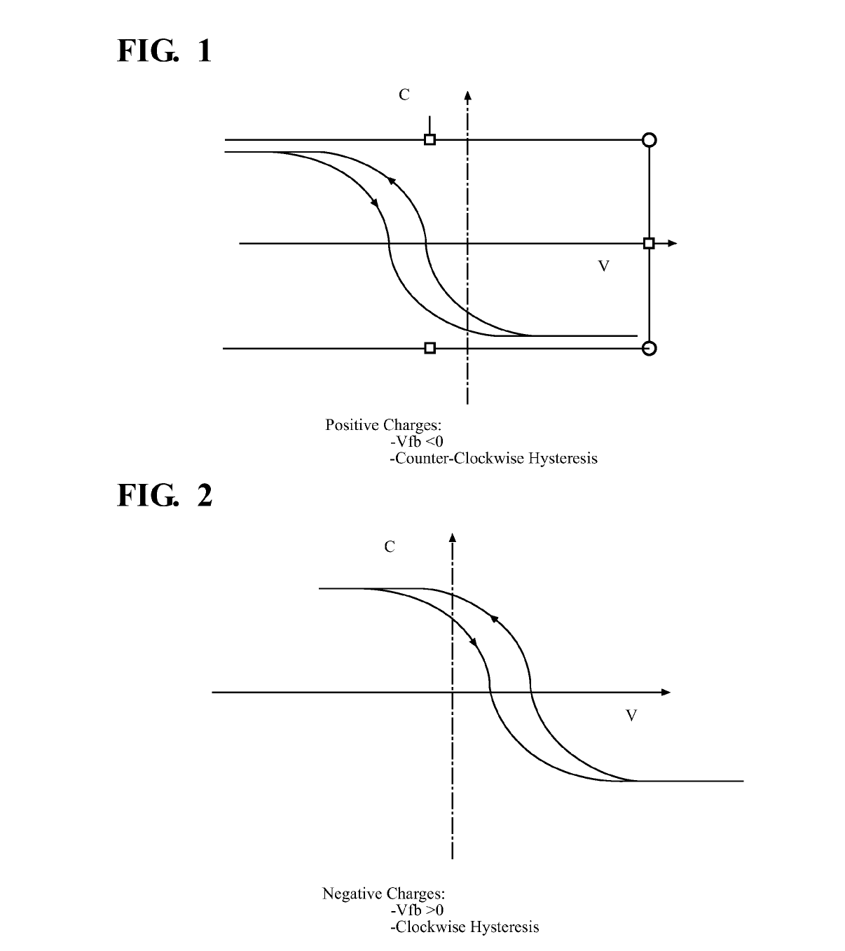

FIG. 1 is a graph plotting capacitance against voltage applied to a complementary metal-oxide-semiconductor structure (CMOS) comprising a p-doped FZ (float zone silicon) wafer and an oxide having positive charges;

FIG. 2 is a graph plotting capacitance against voltage applied to a CMOS structure comprising a p-doped FZ wafer and an oxide having negative charges;

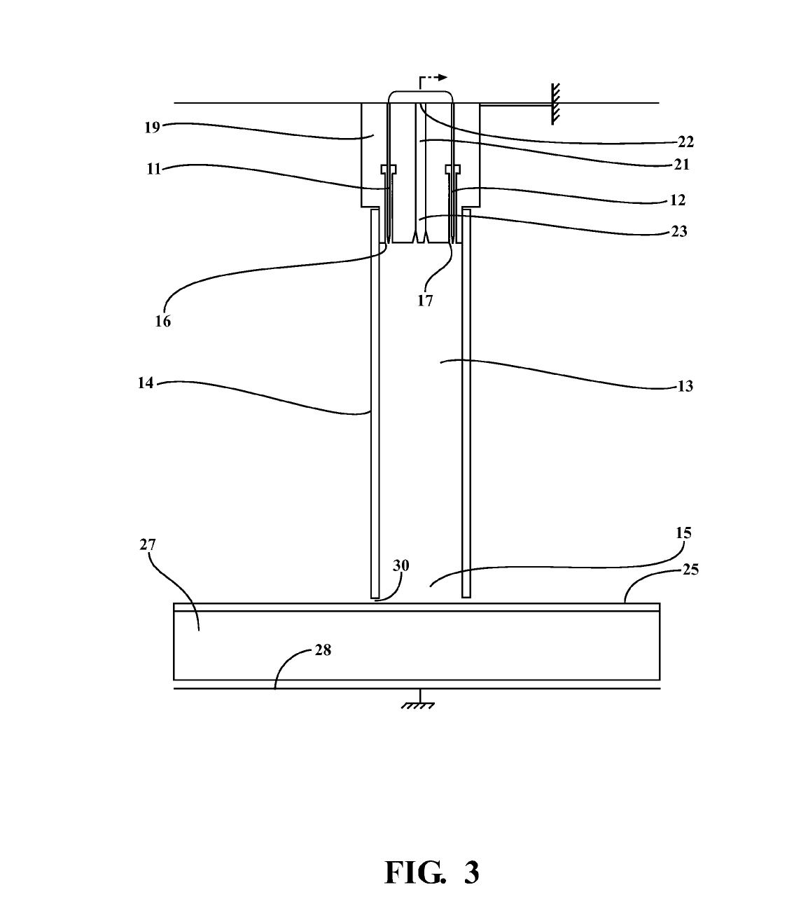

FIG. 3 is a schematic cross section of an apparatus according to the invention for depositing a silicon compound layer from a non-equilibrium atmospheric pressure plasma incorporating an atomised organosilicon compound;

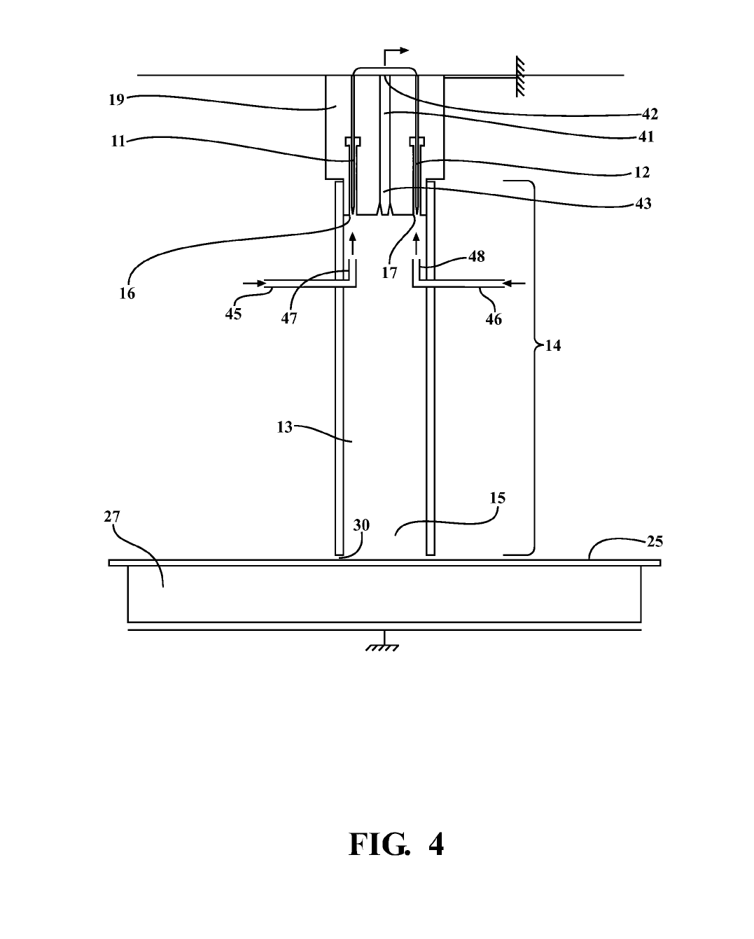

FIG. 4 is a diagrammatic cross section of an alternative apparatus according to the invention for depositing a silicon compound layer from a non-equilibrium atmospheric pressure plasma incorporating an atomised organosilicon compound;

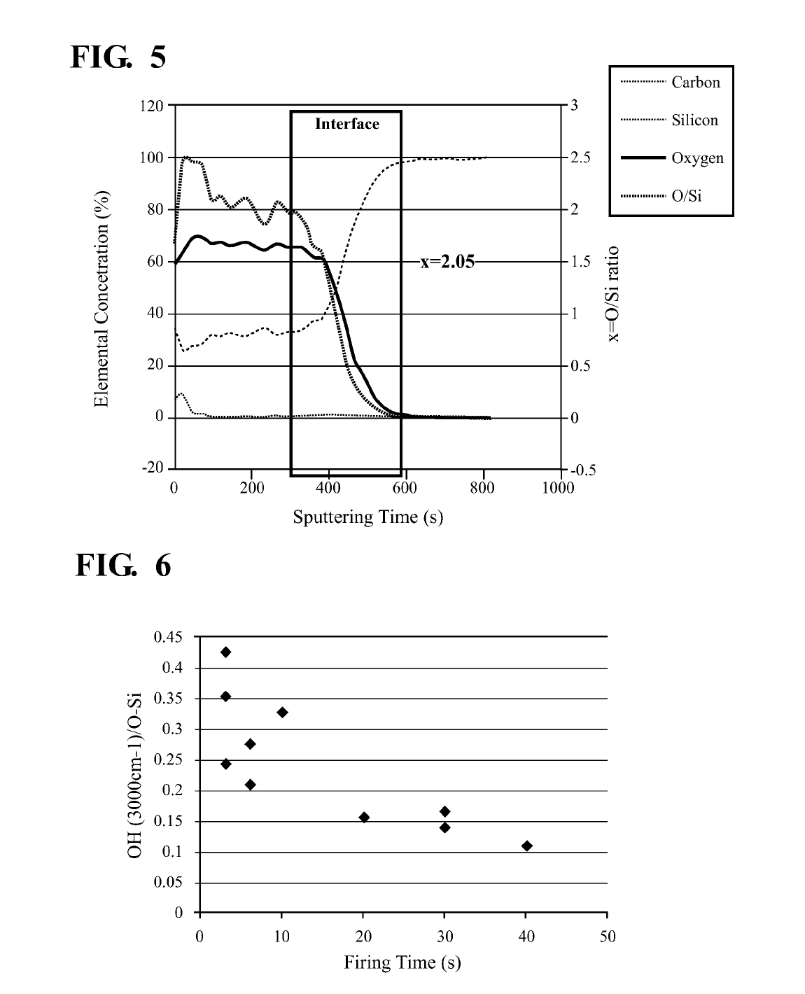

FIG. 5 is a graph plotting the profile of elemental concentration of oxygen and silicon of the product of Example 4 as measured by dynamic SIMS analysis; the x axis is the sputtering time corresponding to depth of SIMS analysis.

FIG. 6 is a graph showing the value of Si—OH bonds density (ratio between the surface area of the Si—OH peak located at 3000 cm⁻¹ to the surface area of the Si—O—Si peak located at 1060 cm⁻¹) as a function of the duration of the thermal annealing step as measured by FTIR in Examples 2, 5 and 6,

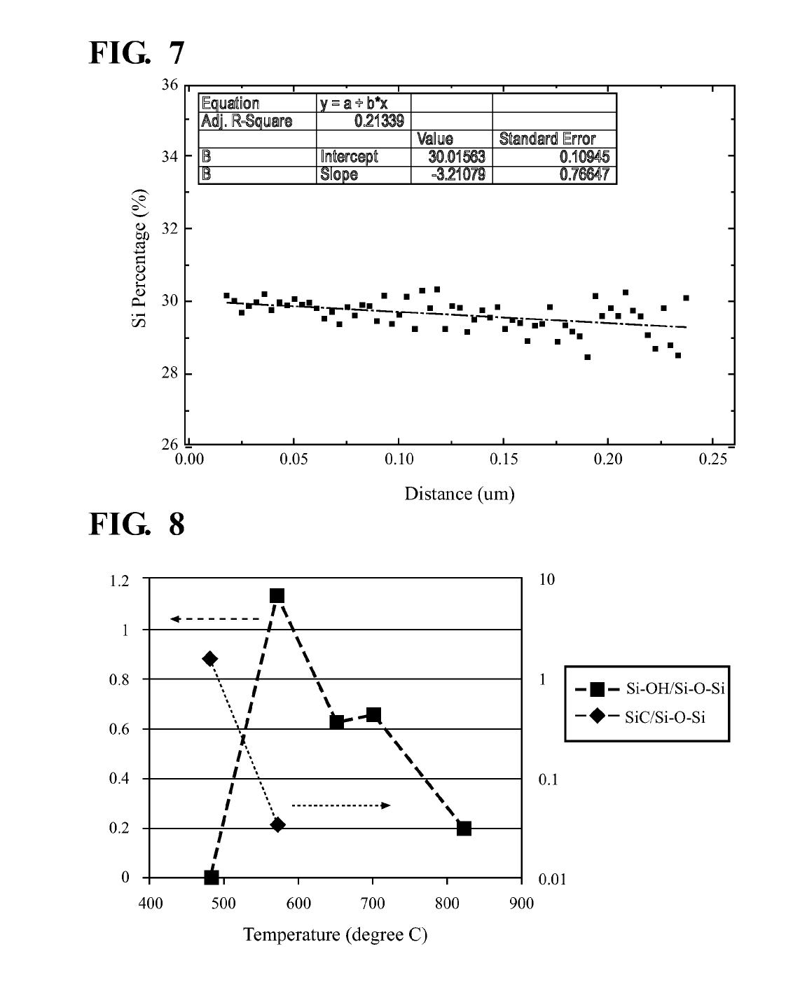

FIG. 7 is a graph of the silicon content in SiOx film measured by EELS-TEM on film corresponding to example 7.

FIG. 8: Evolution of the area of FTIR peak around 1200 cm⁻¹ divided by main Si—O—Si peak located at 10060 cm⁻¹ (characteristic of carbon content) and areas of Si—OH peak over Si—O—Si peak area in function of the film annealing temperature in air

The density and sign of fixed charges and the density of interface traps are both parameters that characterize the quality of an oxide and the quality of the interface between the oxide and the silicon wafer. These parameters can be estimated through use of C-V (Capacitance-Voltage) measurements of the film, which use requires integrating of these films in very specific device structure like a CMOS (Complementary metal-oxide-semiconductor) To build a CMOS, an oxide layer (of thickness between 40 and 100 nm) is deposited onto a FZ wafer (for our measurement, we used p-doped wafers double side polished wafers); then, metal is deposited on both the wafer and oxide sides to create a CMOS structure. When applying a voltage to a CMOS structure and measuring capacitance (moving from negative voltage to positive voltage and vice-versa), we obtain curves showing hysteresis.

With a p-type wafer, when a negative voltage is applied to the electrodes, we have accumulation of the majority carriers (the holes) to the interface between the wafer and the silicon oxide. The assembly behaves like a capacitor of dielectric thickness equal to the thickness of the oxide itself. When decreasing voltage to zero, the capacitance decreases to reach a minimum; when applying positive voltage, we are in inversion mode which means that minority carrier (electrons for a p-type wafer) move to the oxide silicon interface, and the capacitance increases again. For CV measurements, a high frequency component is applied to the DC component, changing the shape of the CV curve shown in FIGS. 1 and 2. The part of the curve representing applied negative voltage is not affected because majority carriers have a high mobility and can follow the rapid change in voltage. This is not the case for minority carriers so that the capacitance measured will stay flat as shown in FIGS. 1 and 2.

If the flat band voltage (voltage associated to the decrease in capacitance) is negative as shown in FIG. 1 when using a p-type wafer, this means that built-in fixed charges in the dielectric are of positive sign, the charge density being calculated from the flat band voltage value. Such positive fixed charges (and hence negative flat band voltage) are typical of silicon oxide layers known for use in PERC photovoltaic cell structure

If the flat band voltage (voltage associated to the decrease in capacitance) is positive as shown in FIG. 2 when using a p-type wafer, this means that built-in fixed charges in the dielectric are of negative sign. The charge density can be calculated from the flat band voltage value. Such negative fixed charges (and hence positive flat band voltage) are found for the silicon oxide layers of the invention of the formula SiOₓ where x has an average value comprised between 2 and 2.6 for example the silicon oxide layer formed in Example 1 which has an x value of 2.35. The silicon wafer coated with a layer of a silicon oxide SiOₓ according to the present invention typically has a density of fixed negative charges of at least 1×10¹¹ cm⁻² and typically between 2×10¹¹ cm⁻² and 1×10¹² cm⁻². Having negative fixed charges is an advantageous property for an oxide incorporated in a PERC architecture when using a p-doped silicon wafer because the built-in electric field favours charge carriers collection.

The hysteresis is associated with the density of interface traps that fill and empty depending on the sign of voltage applied. When positive fixed charges are present, hysteresis is counter clockwise as in FIG. 1, while when negative charges are present, hysteresis is clockwise as in FIG. 2. The density of interface traps can be calculated from this hysteresis. The silicon wafer coated with a layer of a silicon oxide SiOₓ where x has a value comprised between 2 and 2.6 according to the present invention typically has a density of interface traps below 7×10¹⁰ eV⁻¹ cm⁻²

A process for depositing a layer of silicon compound from a non-local thermal equilibrium atmospheric pressure plasma will be described with reference to FIG. 3 of the accompanying drawings. The apparatus of FIG. 3 comprises two electrodes (11, 12) positioned within a plasma tube (13) defined by a dielectric housing (14) and having an outlet (15). The electrodes (11, 12) are needle electrodes both having the same polarity and are connected to a suitable power supply. Although the power supply to the electrode or electrodes may operate at any frequency between 0 to 14 MHz (0 MHz means direct current discharge), it is preferably a low to radio frequency power supply as known for plasma generation, that is in the range 3 kHz to 300 kHz. The root mean square potential of the power supplied is generally in the range 1 kV to 100kV, alternatively between 4kV and 30kV.

The electrodes (11, 12) are each positioned within a narrow channel (16 and 17 respectively), for example of radius 0.1 to 5 mm, alternatively 0.2 to 2 mm, greater than the radius of the electrode, communicating with plasma tube (13). Each channel (16, 17) has an entry which forms the inlet for process gas into the apparatus and an exit into the plasma tube (13). Each channel (16, 17) preferably has a ratio of length to hydraulic diameter greater than 10:1. The tip of each needle electrode (11 and 12) is positioned close to the exit of the associated channel (16 and 17 respectively). Preferably the needle electrode extends from the channel entry and projects outwardly from the channel (16, 17) so that the tip of the needle electrode is positioned in the dielectric housing close to the exit of the channel at a distance outside the channel of at least 0.5 mm up to 5 times the hydraulic diameter of the channel.

The process gas is fed to a chamber (19) whose outlets are the channels (16, 17) surrounding the electrodes. The chamber (19) is made of a heat resistant, electrically insulating material which is fixed in an opening in the base of a metal box. The metal box is grounded but grounding of this box is optional. The chamber (19) can alternatively be made of an electrically conductive material, provided that all the electrical connections are insulated from the ground, and any part in potential contact with the plasma is covered by a dielectric.

An atomizer (21) having an inlet (22) for organosilicon compound is situated adjacent to the electrode channels (16, 17) and has atomising means (not shown) and an outlet (23) feeding atomised organosilicon compound to the plasma tube (13). The organosilicon compound introduced by the atomiser (21) interacts with the non-local thermal equilibrium atmospheric pressure plasma. The chamber (19) holds the atomiser (21) and needle electrodes (11, 12) in place.

The dielectric housing (14) can be made of any dielectric material. Experiments described below were carried out using quartz dielectric housing (14) but other dielectrics, for example glass or ceramic or a plastic material such as polyamide, polypropylene or polytetrafluoroethylene, for example that sold under the trade mark ‘Teflon’, can be used. The dielectric housing (14) can be formed of a composite material, for example a fibre reinforced plastic designed for high temperature resistance.

The silicon wafer (25) substrate to be coated is positioned at the plasma tube outlet (15) so that the surface of the silicon wafer substrate is in contact with activated species and organosilicon compound fragments generated by plasma-organosilicon compound interaction. The non-local thermal equilibrium atmospheric pressure plasma may extend from the electrode to the outlet of the dielectric housing so that the surface of the silicon wafer adjacent to the outlet of the dielectric housing is in contact with the plasma. However the plasma need not extend to the outlet of the dielectric housing provided that the silicon wafer substrate is in contact with activated species and organosilicon compound fragments generated by plasma-organosilicon compound interaction. Such activated species and organosilicon compound fragments can be conveyed by the process gas flow, diffusion and possibly the electric field to the surface of the silicon wafer substrate. The silicon wafer substrate (25) is laid on a support (27, 28). The silicon wafer substrate (25) is arranged to be movable relative to the plasma tube outlet (15). The support (27, 28) can for example be a dielectric layer (27) covering a metal supporting plate (28). The dielectric layer (27) is optional. The metal plate (28) as shown is grounded but grounding of this plate is optional. If the metal plate (28) is not grounded, this may contribute to the reduction of arcing onto the silicon wafer substrate.

The gap (30) between the outlet end of the dielectric housing (14) and the silicon wafer substrate (25) is the only outlet for the process gas fed to the plasma tube (13). The surface area of the gap (30) between the outlet of the dielectric housing and the substrate is preferably less than 35 times the area of the inlet or inlets for process gas. If the dielectric housing has more than one inlet for process gas, as in the apparatus of FIG. 3 which has inlet channels (16) and (17), the surface area of the gap between the outlet of the dielectric housing and the substrate is preferably less than 35 times the sum of the areas of the inlets for process gas.

When an electric potential is applied to the electrodes (11, 12), an electric field is generated around the tips of the electrodes which ionizes the gas to form plasma. The sharp point at the tips of the electrodes aids the process, as the electric field density is inversely proportional to the radius of curvature of the electrode. Needle electrodes (such as 11, 12) possess the benefit of creating a gas breakdown using a lower voltage source because of the enhanced electric field at the sharp extremity of the needles.

The plasma generating apparatus described can operate without special provision of a counter electrode. Alternatively a grounded counter electrode may be positioned at any location along the axis of the plasma tube.

The power supply to the electrode or electrodes is a low frequency power supply as known for plasma generation, that is in the range 3 kHz to 300 kHz. Our most preferred range is the very low frequency (VLF) 3 kHz-30 kHz band, although the low frequency (LF) 30 kHz-300 kHz range can also be used successfully. One suitable power supply is the Haiden Laboratories Inc. PHF-2K unit which is a bipolar pulse wave, high frequency and high voltage generator. It has a faster rise and fall time (<3 μs) than conventional sine wave high frequency power supplies. Therefore, it offers better ion generation and greater process efficiency. The frequency of the unit is also variable (1-100 kHz) to match the plasma system. An alternative suitable power supply is an electronic ozone transformer such as that sold under the reference ETI110101 by the company Plasma Technics Inc. It works at fixed frequency and delivers a maximum power of 100 Watt with a working frequency of 20 kHz.

The atomizer (21) preferably uses a gas to atomize the organosilicon compound.

For example the process gas used for generating the plasma is used as the atomizing gas to atomise the organosilicon compound. The atomizer (21) can for example be a pneumatic nebuliser, particularly a parallel path nebuliser such as that sold by Burgener Research Inc. of Mississauga, Ontario, Canada, under the trade mark Ari Mist HP, or that described in U.S. Pat. No. 6,634,572. The atomizer can alternatively be an ultrasonic atomizer in which a pump is used to transport the liquid organosilicon compound into an ultrasonic nozzle and subsequently it forms a liquid film onto an atomising surface. Ultrasonic sound waves cause standing waves to be formed in the liquid film, which result in droplets being formed. The atomiser preferably produces drop sizes of from 1 to 100 μm, alternatively from 1 to 50 μm. Suitable atomisers for use in the present invention include ultrasonic nozzles from Sono-Tek Corporation, Milton, N.Y., USA. Alternative atomisers may include for example electrospray techniques, methods of generating a very fine liquid aerosol through electrostatic charging. The most common electrospray apparatus employs a sharply pointed hollow metal tube, with liquid pumped through the tube. A high-voltage power supply is connected to the outlet of the tube. When the power supply is turned on and adjusted for the proper voltage, the liquid being pumped through the tube transforms into a fine continuous mist of droplets. Inkjet technology can also be used to generate liquid droplets without the need of a carrier gas, using thermal, piezoelectric, electrostatic and acoustic methods.

While it is preferred that the atomiser (21) is mounted within the housing (14), for example surrounded by the chamber (19), an external atomiser can be used. This can for example feed an inlet tube having an outlet in similar position to outlet (23) of nebulizer (21) to feed the organosilicon compound in a gaseous state. Alternatively the organosilicon compound, for example in a gaseous state, can be incorporated in the flow of process gas entering chamber (19) either from the channels (17) or through a tube positioned at the location of the nebulizer. In a further alternative the electrode can be combined with the atomizer in such a way that the atomizer acts as the electrode. For example, if a parallel path atomizer is made of conductive material, the entire atomizer device can be used as an electrode. Alternatively a conductive component such as a needle can be incorporated into a non-conductive atomizer to form the combined electrode-atomiser system.

The process gas flow from the inlet past the electrode preferably comprises helium or argon or another inert gas such as nitrogen, or a mixture of any of these gases with each other or with oxygen. Alternatively the process gas generally comprises from 50% by volume helium, argon or nitrogen, to 100% by volume helium, argon or nitrogen, alternatively from 50% to 99% optionally with up to 5 or 10% of another gas, for example oxygen. Specific examples of process gas mixtures which could be used are a mixture of 92% helium, 7.7% nitrogen and 0.3% oxygen, a mixture of 92% argon, 7.7% nitrogen and 0.3% oxygen or alternatively a mixture of 98% nitrogen with 2% oxygen. A higher proportion of an oxidizing gas such as oxygen can also be used if it is required to react with the organosilicon compound. Sometimes no external oxygen is necessary as the oxygen atoms, if any, chemically bound within the organosilicon compound may participate in formation of oxide like film.

The velocity of the process gas flowing past the electrode through channels (16, 17) is preferably less than 100 m/s. The velocity of the process gas, for example helium flowing past the electrodes (11, 12) may be from 3.5 m/s to up to 70 m/s, alternatively at least 5 m/s up to 70 m/s or alternatively from 10 m/s to 50 m/s, alternatively from 10 m/s to 30 or 35 m/s. To promote turbulent gas flow in the plasma tube (13) and thus form a more uniform plasma, it may be preferred to also inject process gas into the dielectric housing at a velocity greater than 100 m/s. The ratio of process gas flow injected at a velocity greater than 100 m/s to process gas flowing past the electrode at less than 100 m/s is preferably from 1:20 to 5:1. If the atomiser (21) uses the process gas as the atomizing gas to atomise the surface treatment agent, the atomiser can form the inlet for the process gas injected at a velocity greater than 100 m/s. Alternatively the apparatus may have separate injection tubes for injecting helium process gas at a velocity of above 100 m/s.

The flow rate of the process gas flowing through the channels (16, 17) past the electrodes (11, 12) is preferably in a range of from 1 slm to 20 L/min, alternatively in the range 2 to 10 L/min. The flow rate of the process gas which has a velocity greater than 100 m/s, for example a process gas such as helium used as the atomising gas in a pneumatic nebuliser, is preferably in the range of 0.5 to 2.5 L/min or alternatively 0.5 to 2 L/min When another process gas than helium is used, for example argon, a lower gas flow through the nebulizer can be used. Because of the much larger mass of argon versus helium the same atomisation performance is achieved with a gas flow 3 times lower. When using argon, gas flow through nebuliser is preferably in the range of 0.15 to 1.2 L/min.

The apparatus of FIG. 4 comprises two electrodes (11, 12) each positioned within a narrow channel (16 and 17 respectively) communicating with plasma tube (13) defined by a dielectric housing (14) and having an outlet (15), all as described above for FIG. 3. Helium process gas is fed to a chamber (19) whose outlets are the channels (16, 17) surrounding the electrodes. The substrate (25) to be treated is positioned at the plasma tube outlet (15) with a narrow gap (30) between the outlet end of the dielectric housing (14) and the substrate (25). The substrate (25) is laid on a dielectric support (27) and is arranged to be movable relative to the plasma tube outlet (15), as described with reference to FIG. 3.

The apparatus of FIG. 4 comprises an atomiser (41) having an inlet (42) for surface treatment agent, atomising means (not shown) and an outlet (43) feeding atomised surface treatment agent to the plasma tube (13). The atomiser (41) does not use gas to atomise the surface treatment agent.

The apparatus of FIG. 4 further comprises injection tubes (45, 46) for injecting helium process gas at a velocity of above 100 m/s. The outlets (47, 48) of the injection tubes (45, 46) are directed towards the electrodes (11, 12) so that the direction of flow of the high velocity process gas from injection tubes (45, 46) is counter to the direction of flow of process gas through channels (16, 17) surrounding the electrodes.

The atomizer (41) can for example be an ultrasonic atomizer in which a pump is used to transport the liquid surface treatment agent into an ultrasonic nozzle and subsequently it forms a liquid film onto an atomising surface. Ultrasonic sound waves cause standing waves to be formed in the liquid film, which result in droplets being formed. The atomizer preferably produces drop sizes of from 1 to 100 μm, more preferably from 1 to 50 μm. Suitable atomizers for use in the present invention include ultrasonic nozzles from Sono-Tek Corporation, Milton, N.Y., USA. Alternative atomizers may include for example electrospray techniques, methods of generating a very fine liquid aerosol through electrostatic charging. The most common electrospray apparatus employs a sharply pointed hollow metal tube, with liquid pumped through the tube. A high-voltage power supply is connected to the outlet of the tube. When the power supply is turned on and adjusted for the proper voltage, the liquid being pumped through the tube transforms into a fine continuous mist of droplets. Inkjet technology can also be used to generate liquid droplets without the need of a carrier gas, using thermal, piezoelectric, electrostatic and acoustic methods.

The organosilicon compound is preferably introduced into the non-local thermal equilibrium atmospheric pressure plasma at a flow rate of at least 1 μl/minute, alternatively at least 2 μl/minute. The organosilicon compound can for example be introduced at a flow rate in a range of from 1 μl/minute to 30 μl/minute, alternatively from 2 μl/minute to 20 μl/minute. In a further alternative the organosilicon compound is introduced at a flow rate of 2 to 14 μl/minute. The rates of deposition on the silicon wafer substrate of the layer of silicon compound from a non-local thermal equilibrium atmospheric pressure plasma using these feed rates of organosilicon compound are generally in the range 3 to 100 nm/s. A layer of silicon compound can thereby be deposited at a much more rapid rate than a dense silicon oxide can be deposited.

The layer of silicon compound deposited on the silicon wafer substrate preferably contains at least 5% carbon but preferably has a lower carbon content than the organosilicon compound precursor. The energy provided by the non-local thermal equilibrium atmospheric pressure plasma promotes partial conversion of the organosilicon compound into a silicate or silica structure with removal of carbon. For example, using the apparatus and flow rates disclosed above for generating the non-local thermal equilibrium atmospheric pressure plasma, the percentage of carbon atoms in the layer of silicon compound deposited from tetramethylcyclotetrasiloxane (CH₃(H)SiO)₄ as precursor is generally less than 33% and is usually in a preferred range of 5 to 30%. If the organosilicon compound precursor is Si(OC₂H₅)₄ the percentage of carbon atoms in the layer deposited is less than 60%. If the organosilicon compound precursor is hexamethyldisiloxane the percentage of carbon atoms in the layer deposited is less than 66%. For all these precursors the percentage of carbon atoms in the layer of silicon compound deposited can be controlled to be in a preferred range, for example 5 to 30%, by varying the flow rates of the process gas, the energy supplied to the discharge and the organosilicon compound precursor within the preferred ranges described above.

An alternative method for deposition of a layer of density at least 1050 kg/m³ of a silicon compound containing 5 to 66% carbon atoms, which can be oxidised by thermal treatment in an oxygen-containing atmosphere at a temperature of at least 600° C. (e.g., at least 600° C.) for 1 to 60 seconds to produce a silicon oxide layer (2) having negative fixed charges and of the formula SiOₓ where x has an average value comprised between 2 and 2.6 is to use a low pressure plasma. The plasma is formed either in the absence of oxygen addition if the precursor molecule already contains oxygen atoms or adding a very small fraction of oxygen if the precursor is oxygen free and is operated at very low power. A silicon compound such as hexamethyldisiloxane or tetraethoxysilane is incorporated in the low pressure plasma and the silicon wafer substrate is positioned in contact with the plasma in the same manner as silicon wafer substrate (25) described above.

In a further alternative method for deposition of a layer of density at least 1050 kg/m³ of a silicon compound containing 5 to 66% carbon atoms on the silicon wafer substrate, which can be thermally treated to produce a silicon oxide layer (2) having negative fixed charges and of the formula SiOₓ where x has an average value comprised between 2 and 2.6, film can be deposited by a wet chemical route. For example a solution containing organo-metallic compound can be chemically polymerised and deposited on the silicon wafer substrate followed by controlled baking to form a film of the required carbon content and density. A process of this type based on sol-gel technology is described by B. E. Yoldas and T. W. O'Keeffe in Applied Optics, Vol. 18, No. 18, 15 Sep. 1979 to deposit a TiO₂—SiO₂ film on a substrate.

We have found that the density of the layer of silicon compound on the silicon wafer substrate deposited generally increases with increasing conversion of the organosilicon compound into a silicate or silica structure and consequent reduction of the percentage of carbon atoms in the layer deposited. The density of the layer of silicon compound deposited is preferably in the range 1200 to 2000 kg/m³, alternatively 1500 to 2000 kg/m³

The layer of silicon compound deposited is oxidized by thermal treatment in an oxygen-containing atmosphere at a temperature of at least 600° C. (e.g., at least 600° C.) for 1 to 60 seconds as described above to produce the silicon oxide layer (2) having negative fixed charges and of the formula SiOₓ where x has an average value comprised between 2 and 2.6. The thickness of the silicon oxide layer (2) produced is generally less than the thickness of the layer of silicon compound initially deposited. The silicon oxide layer (2) is preferably from 50 nm to 600 nm thick. The thickness of the passivation layer of silicon oxide dielectric material is alternatively from 150 nm to 400 nm.

In the production of a photovoltaic cell, a silicon wafer coated with a passivation layer of a silicon oxide produced as described above has back contacts formed through the silicon oxide layer. To fully develop its passivation ability, the silicon wafer coated with the passivation layer of silicon oxide is submitted to hydrogenation. This may be achieved either by forming gas annealing in an atmosphere containing hydrogen or by depositing a silicon nitride layer and firing the assembly of layers.

In a preferred process, an amorphous hydrogenated layer of a silicon nitride is deposited over the silicon oxide layer, and back contacts are formed through the silicon nitride and silicon oxide layers. The formation of such back contacts is a known process described for example in US-A-2009/0301557. Contacts are formed by forming holes in the dielectric silicon oxide layer and silicon nitride layer and depositing a layer of contacting material, thereby filling the holes. The holes may be formed by laser ablation, by applying an etching paste, or by mechanical scribing. The layer of contacting material, for example a metal such as aluminium, can be deposited by evaporation, sputtering, screen printing, inkjet printing, or stencil printing. It can be deposited locally essentially in the holes or as a continuous or discontinuous layer. After the contacting material has been applied, the photovoltaic cell can be subjected to a firing step, for example in the range 600 to 1000° C. for 5 to 60 seconds.

In an alternative hydrogenation process, the silicon dioxide layer is heated in an atmosphere comprising hydrogen. The atmosphere preferably contains 2 to 20% by volume hydrogen in an inert gas such as nitrogen. This type of hydrogenation process is preferably carried out at a temperature in the range 350° C. to 500° C., for example at about 400° C. The time for which hydrogenation is carried out can for example be in the range 10 to 60 minutes or more. However the formation of back contacts will require a subsequent firing step, for example in the range 600 to 1000° C. as described above.

The silicon oxide layer (2) of the formula SiOₓ where x has an average value greater comprised between 2 and 2.6 shows a negative fixed charge and has a low density of interface traps. We have found that photovoltaic cells, particularly solar cells, comprising such a silicon oxide layer (2) show improved passivation. We believe that the improved passivation results from the negative fixed charges of the silicon oxide layer (2) of the formula SiOₓ where x has an average value greater comprised between 2 and 2.6. The silicon oxide contains silanols at a concentration such that the area of the Si—OH peak located at 3000 cm⁻¹ to the Si—O—Si peak located at 1060 cm⁻¹ of film absorbance measured by FTIR is comprised between 0.05 and 0.8. The range in material properties is illustrated in FIG. 8 that shows the evolution of the area of FTIR peak around 1200 cm⁻¹¹ (characteristic of carbon content) divided by main Si—O—Si peak area located at 1060 cm⁻¹ and areas of Si—OH peak over Si—O—Si peak in function of film annealing temperature in air. Material subjected to this invention has no detectable carbon and contains Si—OH so that area of the Si—OH peak located at 3000 cm−1 to the Si—O—Si peak located at 1060 cm⁻¹ of film absorbance measured by FTIR is comprised between 0.05 and 0.8.

Passivation can for example be measured by calculating the minority carrier lifetime using a μ-PCD (microwave detected photoconductive decay) device. The minority carrier lifetime is measured after hydrogenation without formation of back contacts. Increased minority carrier lifetime shows improved passivation. A suitable μ-PCD device is for example supplied by SemiLab under the trade mark WT-2000. In the μ-PCD technique, the time decay of photo carriers generated by a laser pulse is measured via the reflection of microwaves by the photo conductive wafer. The μ-PCD method typically operates at very high injection with a very short light pulse of only 200 ns.

In an alternative test procedure for measuring passivation, lifetime is measured using a QSSPC (quasi steady state photoconductivity) measurement method. QSSPC detects the changes in permeability of the sample and therefore the conductance via the coupling of the sample by a coil to a radio-frequency bridge. The exciting light is tuned down slowly, so that sample is always in a quasi steady state. In both test procedures, a longer lifetime indicates improved passivation.

The invention is illustrated by the following Examples, in which percentages of elements expressing the atomic fractions of atoms constituting the film, excluding hydrogen, are measured by XPS, SIMS and EELS-TEM. SIMS and EELS-TEM are also used for measuring the width of the interface between the silicon oxide and the wafer, a higher accuracy being given by the TEM device. XPS analysis was performed using an Axis Ultra spectrometer (Kratos Analytical). Samples were irradiated with monochromated x-rays (Al Kα, 1486.6 eV) with photoelectrons analyzed from a selected area 700 μm by 300 μm, with a take-off-angle of 90°. Experience with similar specimens indicated that differential charging was likely. To obtain good spectra the instrument's charge neutralization system was used. Each analysis position was analyzed in the survey mode (Pass Energy 160 eV) to determine the elements that were present at the surface and their relative concentrations. Casa XPS (Casa Software Ltd) data processing software was used to calculate the area under peaks representative of elements detected, which were then normalized to take into account relative sensitivity to provide relative concentrations. Each analysis position was also analyzed in the high resolution mode (Pass Energy 20 eV) to determine more detailed information on the elements present at the surface. The time delay between film formation and XPS measurement was kept minimum. Samples were stored in a clean plastic box right after SiOx film formation to minimize contamination. No extra treatment was applied after film formation process to avoid further samples manipulation.

Thermal treatment in the Examples was by RTP furnace supplied by SSI. Where a 1 second value is stated for time at the maximum set point temperature, cool-down took place immediately once the maximum temperature was reached; even if thermal inertia of the RTP furnace is low, we may consider that the wafer is exposed at the peak temperature for about one 1 second.

### EXAMPLE 1

The apparatus of FIG. 3 was used to deposit a layer of an organosilicon compound on a conductive silicon wafer substrate. The dielectric housing (14) defining the plasma tube (13) was 18 mm in diameter. This housing (14) is made of quartz. The electrodes (11, 12) were each 1 mm diameter and were connected to the Plasma Technics ETI110101 unit operated at 20 kHz and maximum power of 100 watts. Helium process gas was flowed through chamber (19) and thence through channels (16, 17) at 2 slm. The channels (16, 17) were each 2 mm in diameter, the electrodes (11, 12) being localized in the centre of each channel. The length of the channels was 30 mm. The tip of each needle electrode (11, 12) was positioned close to the exit of the channel (16, 17 respectively) at a distance 0.5 mm outside the channel exit.

The atomiser (21) was the Ari Mist HP pneumatic nebuliser supplied by Burgener Inc. Tetramethyltetracyclosiloxane was supplied to the atomiser (21) at 2 μL/m. Helium was fed to the atomiser (21) as atomising gas at 2.2 slm -. The gap (30) between quartz housing (14) and the silicon wafer substrate was 2 mm.

4 inches (10 cm) diameter Float Zone silicon circular wafers 350 nm thick were used as substrate to produce an assembly suitable for surface passivation measurement. Wafers were cleaned with a standard Pyrana recipe used in microelectronics followed by a 5 seconds dip in a 5% by weight HF solution. Two smooth organosilicon compound films were deposited on both the top side and the rear side of the wafer, deposition time being controlled to 660 seconds to have a thickness of ˜500 nm before the thermal treatment. The carbon content of the organosilicon compound layer was measured by XPS as 20.5%. The density of the organosilicon compound layer was found to be 1290 kg/m³ estimated through measurement of the mass of the film using a Sartorius scale with a precision of 1e-5 gram and its thickness using a Jobin Yvon UVsel spectroscopic Ellipsometer

The coated wafer was thermally treated in air by exposure of both organosilicon compound layers to contact firing at a peak temperature of 850° C. for 1 second. The time to reach maximum temperature was 6 seconds. The silicon compound layers were densified and converted to silicon oxide. The silicon oxide layers produced had no carbon content detectable by XPS Each silicon oxide layer was ˜250 nm thick.

The elemental composition of the silicon oxide layer (2) on the back surface of the silicon wafer substrate (1) was measured by XPS that shows an oxygen to silicon content ratio equal to 2.35. FTIR measurement of the film shows a broad peak around k=3000 cm−1 which is the signature of Si—OH bonds; relative density of Si—OH bonds and Si—O—Si bonds was measured calculating the ratio between the surface area of this peak and the surface area of the main Si—O—Si peak centred on ˜1060 cm⁻¹.

The silicon oxide layer (2) at the back face of the silicon wafer substrate (1) was hydrogenated by exposure to 10% by volume H₂ diluted in N₂ at 400° C. for 30 minutes. The passivation performance was measured using a μ-PCD device supplied by SemiLab and was found to have a lifetime value of 170 μs.

### EXAMPLES 2 TO 4

Example 1 was repeated using varying flow rates of the tetramethyltetracyclosiloxane (TMCTS) precursor as shown in Table 1. In each Example the carbon content of the organosilicon compound layer deposited from the non-local thermal equilibrium atmospheric pressure plasma on the silicon wafer substrate was measured by XPS and the density of this organosilicon compound layer was measured; the results are shown in Table 1.

In each Example 2 to 4, the elemental composition of the silicon oxide layer on the back surface of the silicon wafer substrate was measured by dynamic SIMS for films being deposited using different precursor flows of 6, 9 and 12 μl/min. The results are shown graphically in FIG. 5 for the 12 μl/min deposition conditions (example 4) which plots elemental concentration of oxygen, silicon and carbon against etching time (time of sputtering in the SIMS analyser). As the dynamic SIMS apparatus continuously removes the outer surface of the sample, the time shown in FIG. 5 is proportional to depth within the sample. As seen in FIG. 5, the silicon wafer substrate is coated with a silicon oxide layer having negative fixed charges and of the formula SiOₓ where x has an average value comprised between 2 and 2.6 as measured by SIMS. There is an interface region between the silicon wafer substrate and the silicon oxide layer. The ratio of oxygen to silicon atoms varies through the depth of the interface region from 0 at the boundary of the silicon wafer and the interface region to x at the boundary of the layer of formula SiOₓ and the interface region. It can be seen that the silicon oxide layer had a substantially constant composition through its depth and was of formula SiOₓ where x=2.05. In comparison, XPS measurement on the film (alternating etching and data acquisition) gives an average x values measured at different position in the film of 2.0.

In FIG. 5, a small amount of carbon is seen in the surface layer. Since there is no carbon in the silicon oxide layer, we believe that the carbon seen in the surface layer is acquired from the environment and is not carbon remaining from the tetramethyltetracyclosiloxane.

For each of Examples 2 to 4 the plot of elemental concentration of oxygen and silicon against etching time was similar to that shown in FIG. 5. Each showed a silicon oxide layer (2) of substantially constant composition through its depth and of formula SiOₓ The value of x in each Example is shown in Table 1.

For each of Examples 1 to 5 the lifetime of a surface passivation testing assembly comprising the silicon wafer coated on both sides with silicon oxide layers subject of this invention and hydrogenated by forming gas annealing, was measured using a μ-PCD device. The results are also shown in Table 1.

We observe for all Examples 2 to 4 a thick interface region where the oxygen to silicon ratio drops from its bulk x value to zero at the silicon wafer substrate surface. This transition zone of varying film composition is sharp, with a width<30 nm as measured by SIMS. We also observe a rather large Si—OH bond density that can be directly related to the lifetimes measured by μ-PCD; it has been explained above that presence of Si—OH results from uncompleted condensation of silanol while thermal treatment is performed. Presence of SiOH bonds in this case seems the most probable reason for the oxygen rich nature of the film. It is remarkable that best wafer surface passivation performances are achieved by films that are not completely converted to dense silicon oxide, which is a surprising result. In addition, we also observed that films having received the same thermal treatment (1 s at 850° C.) may have different Si—OH content depending on the initial structure and composition of as deposited film, specially its carbon content.

TABLE 1

| | | | Value of x in | | Width of | | |
|---|---|---|---|---|---|---|---|
| | | Carbon content | SiOₓ after | | interface | | |
| | TMCTS flow | by XPS | thermal treatment | x after thermal | measured | Si—OH | Lifetime |
| Ex. No. | (μl/min) | (atomic %) | (SIMS) | treatment - XPS | by SIMS | bonds density | in μs |
| 1 | 2 | 20.5 | Not measured | 2.35 | Not measured | 0.22 | 170 |
| 2 | 6 | 26 | 2.5 | Not measured | 29 nm | 0.35 | 255 |
| 3 | 9 | 29 | Not measured | Not measured | Not measured | 0.37 | 280 |
| 4 | 12 | 33 | 2.05 | Not measured | 26 nm | 0.42 | 250 |

### EXAMPLES 5 AND 6

Organosilicon compound layers with a carbon content of 26% were deposited on silicon wafer substrates using the process of Example 2, i.e. the experimental conditions of Example 1 but with TMCTS flow rate of 6 μL/min.

Each coated wafer was thermally treated in air by exposure of both organosilicon compound layers to annealing at a maximum temperature of 850° C. The time to reach maximum temperature is 6 seconds. The time of firing at the maximum temperature of 850° C. was varied as shown in Table 2.

In each Example the elemental composition of the silicon oxide layer on the back surface of the silicon wafer substrate was measured by dynamic SIMS. For each of Examples 5 and 6, the plot of elemental concentration of oxygen and silicon against etching time was of similar general shape to that shown in FIG. 5. Each showed a silicon oxide layer of substantially constant composition through its depth and of formula SiOₓ. The value of x in each Example is shown in Table 2. The SIMS plot of elemental concentration of oxygen and silicon against etching time shows the change in film composition close to the interface. Values of interface thickness are also reported in table 2. We observed that when applying a very short firing, the interface is sharp and ˜20 nm as measured by SIMS. When applying a longer firing of 60 s duration (treatment leading to elimination of silanols), the interface broadens to reach 32 nm measured by SIMS. In addition, the Si—OH bond density was measured calculating the ratio between the Si—OH peak around 3000 cm⁻¹ and the Si—O—Si peak at 1060 cm⁻¹ of the FTIR absorption spectrum. It is observed (Table 2) that when the annealing time increases, the Si—OH bond density decreases, suggesting a more completed conversion of the film to SiO₂. Finally, the x value (oxygen to silicon ratio) measured by SIMS showed a decrease of x from ˜2.5 to 2.3 when increasing the thermal budget of firing step, this result being consistent with the decrease in silanols concentration measured by FTIR.

The silicon oxide layer at the back face of each silicon wafer substrate was hydrogenated by exposure to 10% by volume H₂ diluted in N₂ at 400° C. for 30 minutes.

For each of Examples 2, 5 and 6 the lifetime of a testing assembly comprising the silicon wafer substrate coated with silicon oxide layers and hydrogenated was measured using a μ-PCD device. The results are shown in Table 2.

In FIG. 6, we show the relative Si—OH concentration as measured by FTIR (we report the surface area of Si—OH peak at ˜3000 cm⁻¹ to Si—O—Si peak surface located at 1060 cm⁻¹) in function of the time of film exposure at high temperature. We observe that the film after firing still contains Si—OH bonds and that Si—OH bonds density decreases when increasing the time of exposure at high temperature, following the reaction 3) described in paragraph [0033] above to lead to a full conversion of the film to SiO₂.

TABLE 2

| | | Value of X | Interface | | |
|---|---|---|---|---|---|
| | Time at | in SiOₓ | thickness | Si—OH bonds | |
| Example | 850 ° C. in | measured | measured | (ratio Si—OH peak to Si—O—Si | Lifetime |
| No. | seconds | by SIMS | by SIMS | peak from FTIR spectrum) | in μs |
| 2 | 1 | 2.5 ± 0.25 | 23 nm ± 5 nm | 0.41 | 255 |
| 5 | 6 | 2.28 ± 0.2 | 19 nm ± 5 nm | 0.365 | 110 |
| 6 | 60 | 2.34 ± 0.2 | 32 nm ± 5 nm | 0.215 | 50 |

### EXAMPLES 7 AND 8

Organosilicon compound layers were deposited on silicon wafer substrates using Argon process gas instead of Helium: the flow of argon was set to 2.5 slm through the channels (16, 17) and 0.3 slm through the atomizer (21). The TMCTS flow was set to 12 μl/leading to the deposition of an organosilicon compound layer of carbon content 28%.

Each coated wafer was thermally treated in air by exposure of both organosilicon compound layers to thermal annealing at a maximum temperature of 850° C. The time to reach maximum temperature is 6 seconds. The time of thermal annealing at the maximum temperature of 850° C. was varied as shown in Table 3.

Because the principle of SIMS technique that consists of etching the film with a high energy ion beam, this method leads to a interface broadening effect that can be minimized but not suppressed working at low energy of etching beam. For this reason, for the next examples, it was decided to complement SIMS measurements by TEM measurement that gives a more accurate measurement of interface thickness.

In each example the elemental composition of the silicon oxide layer on the back surface of the silicon wafer substrate was measured by EELS-TEM. The plot of elemental concentration of oxygen and silicon in function of the position in the film is given in FIG. 7 for example 7. We observe a silicon oxide layer of substantially constant composition through its depth and of formula SiOₓ. The value of x in each example is shown in Table 3. In addition, interface thickness was also measured by looking at the change in film composition. Values are also reported in table 3. We will notice than thicknesses reported are smaller than for example 5 and 6 reported in table 2. As expected, the TEM measurement technique gives a smaller value for interface width than values measured by SIMS because of the broadening of interface associated to the SIMS measurement itself. We observed that when applying a very short firing, the interface is sharp and <˜10 nm as measured by TEM. When applying a longer firing of 60 s duration (treatment leading to full elimination of silanols), the interface broadens to reach 16 nm. In addition, the Si—OH bond density was measured calculating the ratio between the Si—OH peak around 3000 cm⁻¹ and the Si—O—Si peak at 1060 cm⁻¹ of the FTIR absorption spectrum. It is observed (Table 3) that when annealing time increases, the Si—OH bond density decreases, suggesting a more completed conversion of the film to SiO₂. Finally, the evolution of X (oxygen to silicon ratio) measured by EELS-TEM in function of firing duration is consistent with the result of example 5 and 6 i.e. that films fired for shorter time period are more oxygen rich, consistent with the silanol level in the film.

The silicon oxide layer at the back face of each silicon wafer substrate was hydrogenated by exposure to 10% by volume H₂ diluted in N₂ at 400° C. for 30 minutes.

For each of Examples 7 and 8, the lifetime of a testing assembly comprising the silicon wafer substrate coated with silicon oxide layers and hydrogenated was measured using a μ-PCD device. The results are shown in Table 3.

TABLE 3

| | | Value of x | | | |
|---|---|---|---|---|---|
| | | in SiOₓ | Interface | | |
| | Time at | measured | thickness | Si—OH bonds | |
| Example | 850 ° C. in | by EELS- | measured | (ratio Si—OH peak to Si—O—Si | Lifetime |
| No. | seconds | TEM | by TEM | peak from FTIR spectrum) | in μs |
| 7 | 1 | 2.47 | 10 nm | 0.4 | 190 |
| 8 | 30 | 2.12 | 16 nm | 0.15 | 66 |

### EXAMPLE 9

The apparatus of FIG. 3 was used to deposit a layer of an organosilicon compound on 4 inches (10 cm) diameter Float Zone circular silicon wafer substrates 350 nm thick. The dielectric housing (14) defining the plasma tube (13) was 18 mm in diameter. This housing (14) is made of quartz. The electrodes (11, 12) were each 1 mm diameter and were connected to the Plasma Technics ETI110101 unit operated at 20 kHz and maximum power of 100 watts. Helium process gas was flowed through chamber (19) and thence through channels (16, 17) at 10 slm. The channels (16, 17) were each 2 mm in diameter, the electrodes (11, 12) being localized in the centre of each channel. The length of the channels was 30 mm. The tip of each needle electrode (11, 12) was positioned close to the exit of the channel (16, 17 respectively) at a distance 0.5 mm outside the channel exit.

The atomizer (21) was the Ari Mist HP pneumatic nebuliser supplied by Burgener Inc. Tetramethyltetracyclosiloxane was supplied to the atomiser (21) at 6 μl/m. Helium was fed to the atomiser (21) as atomising gas at 2.2 slm. The gap (30) between quartz housing (14) and the silicon wafer substrate was 1.25 mm.

Smooth organosilicon compound films were deposited on both the top side and the rear side of the silicon wafer substrate, deposition time being controlled to 660 seconds to have a thickness of organosilicon compound of ˜500 nm prior to thermal treatment. These organosilicon compound films possess a carbon content of 26%.

The coated wafer was thermally treated in air by exposure of both silicon compound layers to thermal treatment at a maximum temperature of 850° C. for 1 second. The time to reach maximum temperature is 6 seconds. The organosilicon compound layers were densified and converted to silicon oxide. The silicon oxide layer had a formula SiOₓ with x=˜2.5 after thermal treatment.

Each coated silicon wafer was overcoated on both sides with an 80 nm thick SiₓN_{y}H_{z} film deposited by a low pressure PE-CVD (Plasma Enhanced Chemical Vapor Deposition) technique.

The lifetime of 270 μs for an injection level of 2×10¹⁵ was measured for this structure, using a QSSPC measurement device supplied by Sinton.

As a comparison, the lifetime of a structure comprising a silicon wafer substrate coated on both sides with a silicon oxide layer deposited by atmospheric pressure chemical vapor deposition (AP-CVD) and overcoated on both sides with a 80 nm thick SiₓN_{y}H_{z} film was measured, using the same QSSPC measurement method. This structure was supplied as suitable for a PERC (Passivated Emitter and Rear Contact) solar cell. Its lifetime was measured as 100 μs for a same injection level of 2×10¹⁵ cm⁻³.

### EXAMPLE 10

The apparatus was operated using process conditions defined in examples 7 and 8 (gap (30) of 1.25 mm) i.e. operating the plasma reactor using argon instead of helium as process gas. The flow of argon was set to 2.5 slm through the channels (16, 17) and 0.3 slm through the atomizer (21). The TMCTS flow was set to 12 μl/min. Under these conditions a carbon rich organosilicon compound film containing 28% of carbon was deposited on the silicon wafer.

The coated wafer was thermally treated in air as described in example 9 leading to the formation of a SiOx film of composition x=2.47.

The resulting coated wafer was overcoated on both sides with a 80 nm thick SiₓN_{y}H_{z} film as described in Example 9. The lifetime of the resulting structure was measured by QSSPC as 500 μs for an injection level of 2×10¹⁵ cm⁻³. It will be seen that this lifetime is 5 times larger than the reference PERC oxide structure measured in Example 9.

### EXAMPLES 11 AND 12

The apparatus and process conditions of example 10 were used to deposit a layer of an organosilicon compound on a 12.5×12.5 cm² pseudo-square monocrystalline silicon wafer substrate 200 μm thick. Deposition time was controlled to 360 seconds in Example 10 and to 720 seconds in Example 11. In each case a smooth organosilicon compound coating having a carbon content of about 28% was deposited. The non-local thermal equilibrium atmospheric pressure plasma deposition process was used to deposit a single organosilicon compound layer on the back side of the silicon wafer as the first step of a solar cell PERC architecture build-up, the front side being a standard state of the art front cell configuration being made of the emitter and of a antireflective SiN:H coating.

The coated silicon wafer substrate was thermally treated in air by exposure of the rear organosilicon compound layer to a maximum temperature of 820° C. for 1 second. The time to reach maximum temperature was 6 seconds. The organosilicon compound layer was densified and converted to a silicon oxide. The silicon oxide layer produced had no carbon content detectable by XPS and was of formula SiOₓ where x=2.47 as measured by TEM. The silicon oxide layer in Example 11 was 150 nm thick and the silicon oxide layer in Example 12 was 300 nm thick.

This rear side SiOx layer (2) was overcoated with a 80 nm thick SiₓN_{y}H_{z} film by a low pressure PE-CVD technique.

Photovoltaic cells were prepared from the resulting structure by opening the rear SiOₓ/SiN_{y}:H stack by laser ablation followed by metallisation via aluminium deposition by screen printing and firing in a belt furnace at a peak temperature of 800° C.

The cells were then characterized through electrical measurements. Cell performances are expressed by the short circuit current, I_{sc} and open circuit voltage V_{oc}. The I_{sc} reflects the quality of the reflector at the rear side and is associated to thickness of the silicon oxide layer and its optical index. The V_{oc} value reflects the quality of rear surface passivation. Light I-V measurement of the PV cell is carried-out under controlled illumination. A voltage source is set up to supply a voltage sweep to the cell and the resulting current is measured. The voltage source is swept from V1=0 to V2=VOC. When the voltage source is 0 (V1=0), the current is equal to the short-circuit current (ISC). When the voltage source is an open circuit (V2=VOC), then the current is equal to zero (I2=0). This measurement is described in the standard IEC 60904-1 (Part 1-Measurements of photovoltaic current-voltage characteristics).

The short circuit current, I_{sc} and open circuit voltage V_{oc} of reference BSF cells and commercially available PERC cells incorporating state of the art AP-CVD silicon oxide were also measured. The reference BSF cells were cells produced with the same batch of wafer but having on the rear side a BSF passivation structure instead of the SiOₓ/SiN_{y}:H PERC architecture. The BSF structure was the standard Aluminum Back Surface Field passivation structure presently used in the photovoltaic industry. (The actual state of the art method for rear side passivation of p-type solar cell is to use aluminum BSF architecture. It consists in depositing an aluminum layer directly onto the rear of silicon wafer (either by screen printing or PVD) and then to fire the wafer; aluminum diffuses into the silicon wafer and creates a eutectic zone. Aluminum diffusion creates local doping of the p-type wafer, creating a localized p+ doped region. This gradient in doping generates an electric field at the rear of the wafer. Electron and holes being of opposite charges, they drift in opposite direction in presence of an electric field due to coulomb force also the local field created at the rear decreases electron-hole recombination. The results are shown in Table 4, each result being the mean of 4 cells tested.

TABLE 4

| | I_{sc} (mA/cm²) | open circuit voltage (mV) |
|---|---|---|
| Example 9 | 36.9 | 638 |
| Example 10 | 37.1 | 637 |
| BSF reference | 36.1 | 623 |
| PERC reference | 37.3 | 639 |

It can be seen from Table 4 that the cells having SiOₓ films according to the present invention have similar performance to the PERC cells incorporating state of the art AP-CVD oxide and better performance than reference cells having BSF passivation, both in terms of short circuit current, I_{sc} and open circuit voltage V_{oc}.

### EXAMPLES 13 AND 14

The apparatus and process conditions of example 9 have been used, except that a shorter deposition time of 85 seconds was used, to coat a silicon wafer substrate with silicon oxide SiOₓ layers having thicknesses of 34 nm and 41 nm respectively with x values of ˜2.5.

For capacitance-voltage measurement, a platinum electrode was attached to the silicon oxide layer and the opposite face of the silicon wafer was coated with aluminium. The capacitance of the SiOx/silicon wafer stack is measured as a function of the applied voltage (up to saturation limit in both polarities) on the structure to measure the capacitance of the layer. From the hysteresis (observed when scanning voltage from negative to positive voltage and vice-versa) and voltage corresponding to the flat band transition, we can calculate

i) the interface density of states (DIT) and
ii) the polarity of the fixed charges and iii) their density.
These results are reported in Table 5.

The same capacitance-voltage measurements were also made on two PERC structures referenced as PERC1 and PERC 2 incorporating state of the art AP-CVD silicon oxide layers of similar thickness, and these results are also reported in Table 5.

TABLE 5

| | | | Flat band | Flat band | |
|---|---|---|---|---|---|
| | | | voltage | voltage | |
| | Oxide | | expressed in | expressed in | Hysteris |
| Sample | thickness | Dit (eV⁻¹, | volts (forward | volts (reverse | [rev- |
| reference | [nm] | cm⁻²⁾ | voltage sweep) | voltage sweep) | forw] |
| PERC 1 | 43.23 | 1.31 × 10¹¹ | −5.33 | −4.47 | 0.86 |
| PERC 2 | 57.44 | 1.02 × 10¹¹ | −9.76 | −8.62 | 1.14 |
| example 12 | 34.23 | 9.28 × 10¹⁰ | 0.23 | −0.30 | −0.53 |
| example 13 | 40.90 | 7.37 × 10¹⁰ | 0.44 | −0.02 | −0.46 |

It will be observed that DIT of the structure made according to the present invention is lower, which implies a better material and interface quality. The forward and reverse voltage associated to the hysteresis is also reported in Table 5. It can be seen that the hysteresis measured on our material is opposite to the hysteresis measured on the structure having a state of the art AP-CVD silicon oxide layer, which means that fixed charges in the material of this invention and in the reference have opposite sign. Generally, it is accepted that deposited silicon oxide layers have fixed positive charges. We believe that the silicon oxide layers produced according to the present invention show fixed negative charge and we believe that this is a cause of the good silicon surface passivation results obtained using films deposited using the method of this invention.

1. A silicon wafer coated with silicon oxide, wherein the silicon oxide has negative fixed charges and comprises an interface region and a bulk region more remote from the silicon wafer than the interface region, wherein the bulk region has the formula SiOₓ where x has a mean value (the bulk value) greater than 2 and less than 2.6 as measured by EELS-TEM, and the interface region has the formula SiO_{y} wherein the ratio y of oxygen to silicon gradually increases over the thickness of the interface region from zero at the silicon wafer to x in the bulk region, the thickness of the interface region being in the range 5 to 20 nm measured by TEM.

2. A coated silicon wafer according to claim 1, wherein the silicon oxide contains Si—OH bonds, the ratio between the surface area of the Si—OH peak located at 3000 cm−1 to the surface area of the Si—O—Si peak located at 1060 cm⁻¹ as measured by FTIR being between 0.05 and 0.8.

3. A coated silicon wafer according to claim 1, wherein the total thickness of the silicon oxide is 60 to 500 nm.

4. A coated silicon wafer according to claim 3, wherein the thickness of the interface region is 10 to 16 nm as measured by TEM.

5. A coated silicon wafer according to claim 1, wherein the silicon oxide has a negative fixed charge of at least 1×1011 cm⁻², preferably between 2×1011 and 1×1012 cm⁻².

6. A coated silicon wafer according to claim 1, wherein the density of interface traps is in the range 1.7×1010 eV⁻¹ cm⁻² to 1.7×1011 eV⁻¹ cm⁻² at the interface between the silicon and the silicon oxide, as measured by Capacitance-Voltage measurement on a complementary metal-oxide-semiconductor (CMOS) structure.

7. A process for the production of a photovoltaic cell, wherein the silicon oxide layer of a silicon wafer coated with silicon oxide according to claim 1 is hydrogenated and back contacts are formed through the silicon oxide layer.

8. A process according to claim 7 characterised in that the silicon oxide layer is hydrogenated by depositing a layer of a silicon nitride over the silicon oxide layer, and back contacts are formed through the silicon nitride and silicon oxide layers.

9. Use of a silicon wafer coated with a silicon oxide layer in accordance with claim 1 in a photovoltaic cell.
